(19) United States
(12) Patent Application Publication
(10) Pub. No.: US 2018/0004281 A1
(43) Pub. Date: Jan. 4, 2018

(54) RECEPTION INTERFACE CIRCUIT AND MEMORY SYSTEM INCLUDING THE SAME

(71) Applicant: Samsung Electronics Co., Ltd., Suwon-si (KR)

(72) Inventors: Dae-Woon KANG, Suwon-si (KR); Siddharth KATARE, Seoul (KR); Jeong-Don IHM, Seongnam-si (KR)

(73) Assignee: Samsung Electronics Co., Ltd., Suwon-si (KR)

(21) Appl. No.: 15/426,526

(22) Filed: Feb. 7, 2017

(30) Foreign Application Priority Data
Jul. 1, 2016 (KR) 10-2016-0083748

(51) Int. Cl. G06F 1/32; G11C 5/14; G11C 7/10

(52) U.S. Cl. CPC G06F 1/3296; G11C 7/1084; G06F 1/3287; G11C 5/145

(57) ABSTRACT

A reception interface circuit includes a reception buffer, a voltage generation circuit and a reception limiting circuit. The reception buffer receives an input signal through an input-output node to generate a buffer signal. The voltage generation circuit generates at least one control voltage based on a reflection characteristic at the input-output node. The reception limiting circuit is connected to the input-output node and limits at least one of a maximum voltage level and a minimum voltage level of the input signal based on the at least one control voltage. Power consumption may be reduced by limiting at least one of the maximum voltage level and the minimum voltage level of the input signal based on the reception characteristic at the input-output node using the reception limiting circuit, and an increased eye margin may be provided in comparison with a conventional termination circuit having the same power consumption.

### CROSS-REFERENCE TO RELATED APPLICATION

This U.S. Non-provisional application claims priority under 35 USC §119 to Korean Patent Application No. 10-2016-0083748, filed on Jul. 1, 2016, in the Korean Intellectual Property Office (KIPO), the disclosure of which is incorporated by reference in its entirety herein.

### BACKGROUND

### 1. Technical Field

Example embodiments relate generally to semiconductor integrated circuits, and more particularly to a reception interface circuit and a memory system including the reception integrated circuit.

### 2. Discussion of the Related Art

In general, a transceiver device includes an interface circuit for receiving and transmitting signals. Reflection of transferred signals may be caused due to impedance mismatching between the transceiver devices, and noise may be caused by the reflection. In addition, as an operation speed of the semiconductor integrated circuit increases, a frequency of transferred signals increases and a swing width of the transferred signals decreases for reducing power consumption. Because of the increased frequency and the decreased swing width of the transferred signals, even a small noise may cause serious performance degradation. A reception device receiving a signal may include an on-die termination (ODT) circuit that includes a termination resistor connected to an input-output node. Integrity of the transferred signal may be enhanced by suppressing the reflection using the ODT circuit. However, power consumption may be increased because of a current through the ODT circuit.

### SUMMARY

Some example embodiments may provide a reception interface circuit capable of reducing power consumption

Some example embodiments may provide a memory system including a reception interface circuit capable of reducing power consumption

According to some example embodiments, a reception interface circuit includes a reception buffer, a voltage generation circuit and a reception limiting circuit. The reception buffer receives an input signal through an input-output node to generate a buffer signal. The voltage generation circuit generates at least one control voltage based on a reflection characteristic at the input-output node. The reception limiting circuit is connected to the input-output node and limits at least one of a maximum voltage level and a minimum voltage level of the input signal based on the at least one control voltage.

According to some example embodiments, a memory system includes a memory device and a memory controller configured to control the memory device. The memory device includes a reception buffer configured to receive an input signal from the memory controller through an input-output node to generate a buffer signal, a voltage generation circuit configured to generate at least one control voltage based on a reflection characteristic at the input-output node and a reception limiting circuit connected to the input-output node and configured to limit at least one of a maximum voltage level and a minimum voltage level of the input signal based on the control voltage.

The reception interface circuit and the memory system according to example embodiments may reduce power consumption by limiting at least one of the maximum voltage level and the minimum voltage level of the input signal based on the reception characteristic at the input-output node using the reception limiting circuit. The power consumption and the performance of the reception interface circuit and the memory system may be controlled conveniently by adjusting the level of the control voltage. In addition, the reception interface circuit according to example embodiments may provide an increased eye margin in comparison with a conventional termination circuit having the same power consumption.

According to some example embodiments a reception limiting circuit comprises an input-output node configured to receive an input signal, a first reflection limiter connected to the input-output node and configured to limit the maximum voltage level of the input signal based on a first control voltage, and a second reflection limiter connected to the input-output node and configured to limit the minimum voltage level of the input signal based on a second control voltage.

### BRIEF DESCRIPTION OF THE DRAWINGS

Example embodiments of the present disclosure will be more clearly understood from the following detailed description taken in conjunction with the accompanying drawings.

The foregoing and other features of inventive concepts will be apparent from the more particular description of non-limiting example embodiments of inventive concepts, as illustrated in the following drawings.

FIG. 1 is a block diagram illustrating a system including a reception interface circuit according to some example embodiments.

FIG. 2 is a flow chart illustrating a method of controlling a reception interface circuit according to some example embodiments.

FIG. 3 is a diagram illustrating a reception interface circuit according to an example embodiment.

FIG. 4 is a waveform diagram for describing a reception characteristic of a reception interface circuit.

FIGS. 5A and 5B are waveform diagrams illustrating eye margins depending on a limiting voltage.

FIG. 6 is a diagram for describing power consumption of a reception interface circuit according to some example embodiments.

FIG. 7 is a diagram illustrating a reception interface circuit according to an example embodiment.

FIGS. 8A and 8B are diagrams for describing a reception interface circuit of a center-tapped termination (CTT) scheme.

FIG. 9 is a diagram illustrating an example of a reference voltage generator included in a voltage generation circuit in FIG. 1.

FIGS. 10 and 11 are diagrams for describing a reception interface circuit of a pseudo-open drain (POD) termination scheme.

FIG. 12 is a block diagram illustrating a memory system according to some example embodiments.

FIG. 13 is a diagram illustrating an interface circuit according to an example embodiment.

FIG. 14 is a diagram illustrating an example embodiment of a transmission driver included in the interface circuit of FIG. 13.

FIG. 15 is a block diagram illustrating a mobile system according to some example embodiments.

### DETAILED DESCRIPTION OF THE EMBODIMENTS

Various example embodiments will be more fully described hereinafter with reference to the accompanying drawings, in which some example embodiments are shown. In the drawings, like numerals refer to like elements throughout. The repeated descriptions may be omitted.

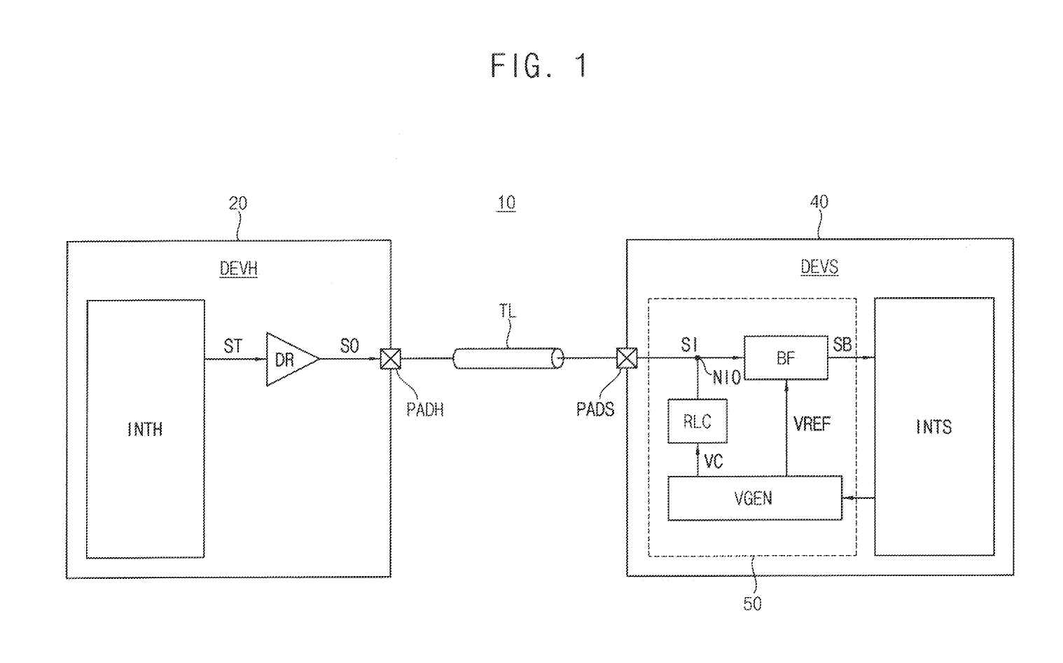

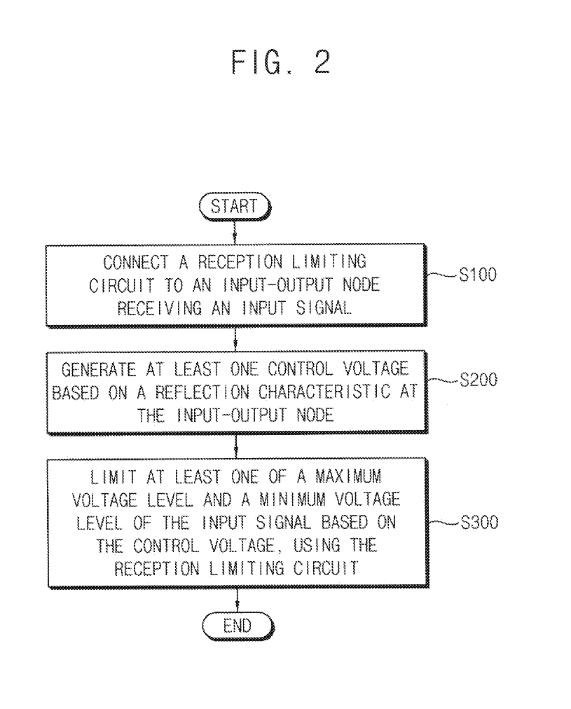

FIG. 1 is a block diagram illustrating a system including a reception interface circuit according to example embodiments, and FIG. 2 is a flow chart illustrating a method of controlling a reception interface circuit according to example embodiments.

Referring to FIG. 1, a system 10 includes a first device DEVH 20, a second device DEVS 40 and a transmission line TL connecting the first device 20 and the second device 40. For example, the first device 20 may be a memory controller and the second device 40 may be a memory device. FIG. 1 illustrates only components for unidirectional communication for convenience of illustration such that the first device 20 functions as a transmitter and the second device 40 functions as a receiver, but each of the first device 20 and the second device 40 may perform bidirectional communication. Even though a pair of input-output pads PADH and PADS and the one transmission line TL connecting the input-output pads PADH and PADS are illustrated in FIG. 1 for convenience of illustration, each of the first device 20 and the second device 40 may include a plurality of input-output pads and a plurality of transmission lines connecting the input-output pads.

A transmission driver DR in the first device 20 may output an output signal SO to the input-output pad PADH based on a transmission signal ST from an internal circuit INTH. A reception interface circuit 50 in the second device 40 may receive an input signal SI through the input-output pad PADS, that is the input-output node NIO to provide a buffer signal SB to an internal circuit INTS.

As illustrated in FIG. 1, the reception interface circuit 50 may include a reception buffer BF, a voltage generation circuit VGEN and a reception limiting circuit RLC. The reception interface circuit 50 may have a configuration for single-ended signaling or pseudo-differential signaling. In fully-differential signaling, the transmitter transmits a transmission signal and its inversion signal, and the receiver compares the two signals for determining a logic high level or a logic low level of the transmission signal. In contrast, in pseudo-differential signaling, the transmitter transmits only the transmission signal and the receiver compares the transmission signal with a reference voltage for determining the logic high level or the logic low level of the transmission signal.

Referring to FIGS. 1 and 2, the reception limiting circuit RLC is connected to the input-output node NIO receiving the input signal SI (S100). The voltage generation circuit VGEN generates at least one control voltage VC based on the reflection characteristic at the input-output node NIO (S200). The reception limiting circuit RLC limits at least one of a maximum voltage level and a minimum voltage level of the input signal SI based on the control voltage VC, using the reception limiting circuit RLC (S300).

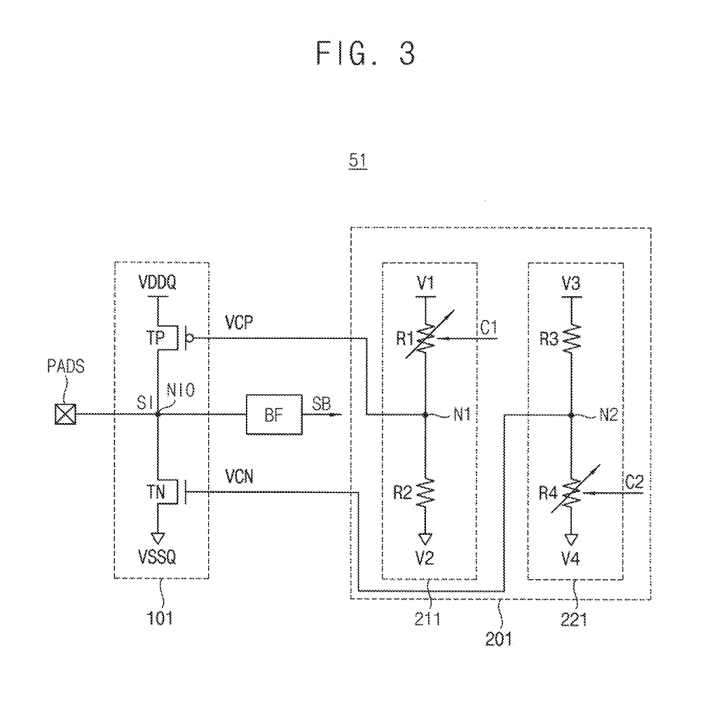

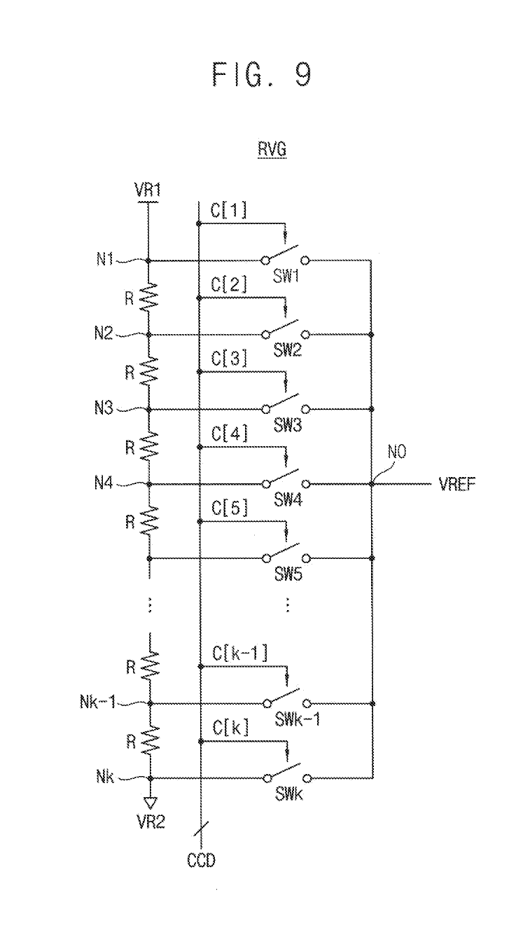

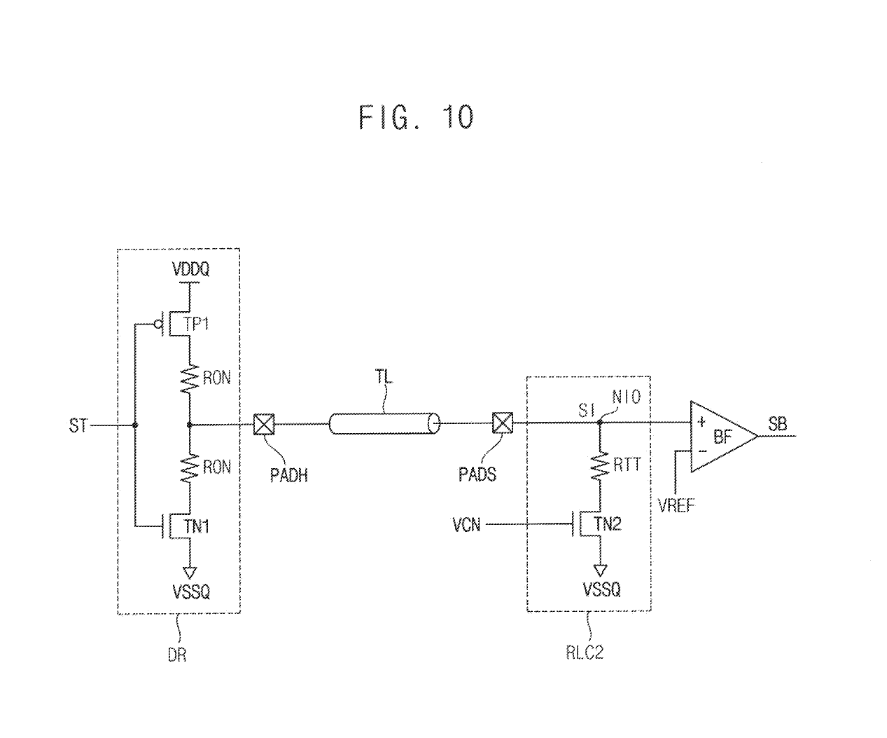

The reception limiting circuit RLC may be implemented with various configurations. In some example embodiments, as will be described below with reference to FIGS. 3, 7 and 8A, the reception limiting circuit RLC may include a first reflection limiter to limit the maximum voltage level of the input signal SI and a second reflection limiter to limit the minimum voltage level of the input signal SI. In other example embodiments, as will be described below with reference to FIG. 10, the reception limiting circuit RLC may include a single reflection limiter to limit the minimum voltage level of the input signal SI. In still other example embodiments, as will be described below with reference to FIG. 11, the reception limiting circuit RLC may include a single reflection limiter to limit the maximum voltage level of the input signal SI.

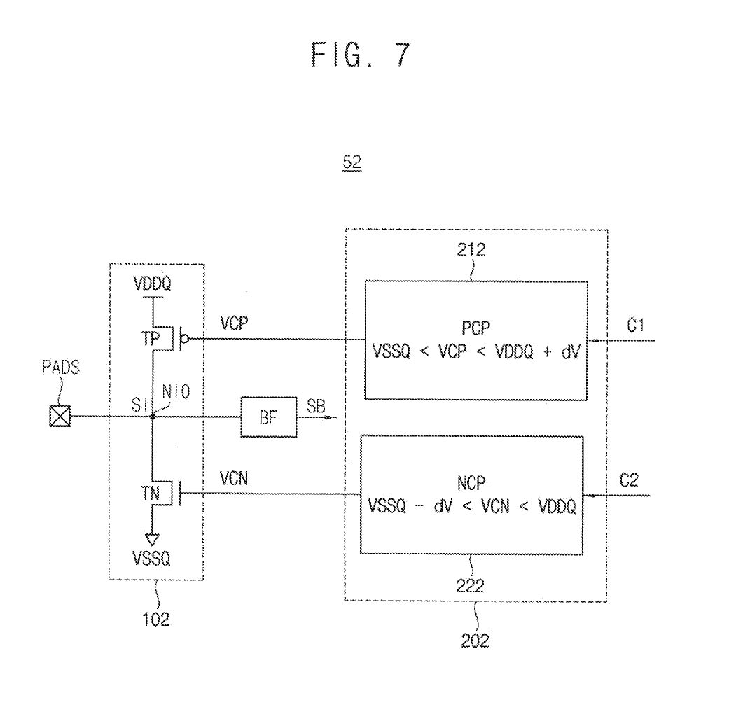

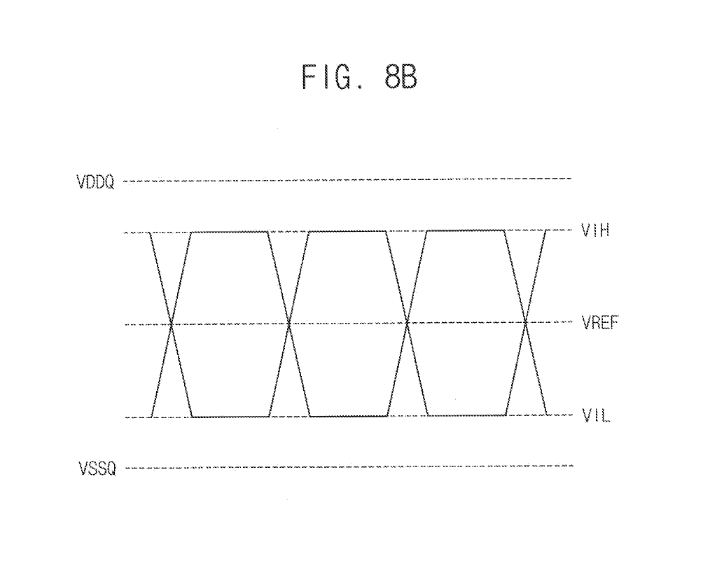

The voltage generation circuit VGEN may have various configurations to generate the control voltage VC. In some example embodiments, as will be described below with reference to FIG. 3, the voltage generation circuit VGEN may include at least one voltage divider to generate the control voltage VC. In other example embodiments, as will be described below with reference to FIG. 7, the voltage generation circuit VGEN may include at least one charge pump to generate the control voltage VC. In some example embodiments, the voltage generation circuit VGEN may further include a circuit configuration to generate a reference voltage VREF. For example, as will be described below with reference to FIG. 9, the voltage generation circuit VGEN may include a reference voltage generator including division resistors to generate the reference voltage VREF.

The reception buffer BF may be implemented according to various embodiments. In some example embodiments, the reception buffer BF may include a differential amplifier receiving complementary two input signals when the reception interface circuit 50 performs the fully-differential signaling. In other example embodiments, the reception buffer BF may include a differential amplifier receiving a single input signal and a reference voltage VREF when the reception interface circuit 50 performs the pseudo-differential signaling.

As such, the reception interface circuit according to example embodiments may reduce power consumption by limiting at least one of the maximum voltage level and the minimum voltage level of the input signal based on the reception characteristic at the input-output node using the reception limiting circuit. The power consumption and the performance may be controlled conveniently by adjusting the level of the control voltage, and an increased eye margin may be provided in comparison with a conventional termination circuit having the same power consumption.

FIG. 3 is a diagram illustrating a reception interface circuit according to an example embodiment.

Referring to FIG. 3, a reception interface circuit 51 may include a reception limiting circuit 101, a reception buffer BF and a voltage generation circuit 201. The reception buffer BF receives an input signal SI through an input-output node NIO to generate a buffer signal BF. The voltage generation circuit 201 generates first and second control voltages VCP and VCN based on a reflection characteristic at the input-output node NIO. The reception limiting circuit 101 is connected to the input-output node NIO and limits at least one of a maximum voltage level and a minimum voltage level of the input signal SI based on the first and second control voltages VCP and VCN.

The reception limiting circuit 101 may include a first reflection limiter TP and a second reflection limiter TN. The first reflection limiter TP is connected between the input-output node NIO and a first power supply voltage VDDQ. The first reflection limiter TP limits the maximum voltage level of the input signal based on the first control voltage VCP. The second reflection limiter TN is connected between the input-output node NIO and a second power supply voltage VSSQ lower than the first power supply voltage VDDQ. The second reflection limiter TN limits the minimum voltage level of the input signal SI based on the second control voltage VCN. The first power supply voltage VDDQ may be a positive voltage and the second power supply voltage VSSQ may be a ground voltage having a voltage level of 0V.

As illustrated in FIG. 3, the first reflection limiter TP and the second reflection limiter TN may be implemented using metal oxide semiconductor transistors. The first reflection limiter TP may include a P-channel metal oxide semiconductor (PMOS) transistor connected between the input-output node NIO and the first power supply voltage VDDQ and the first control voltage VCP may be applied to a gate electrode of the PMOS transistor. The second reflection limiter TN may include an N-channel metal oxide semiconductor (NMOS) transistor connected between the input-output node NIO and the second power supply voltage VSSQ and the second control voltage VCN may be applied to a gate electrode of the NMOS transistor.

The voltage generation circuit 201 may include a first voltage divider 211 configured to generate the first control voltage VCP and a second voltage divider 221 configured to generate the second control voltage VCN.

As illustrated in FIG. 3, the first voltage divider 211 and the second voltage divider 221 may be implemented using division resistors R1, R2, R3 and R4. The first voltage divider may include a first resistor R1 connected between a first voltage V1 and a first node N1 and a second resistor R2 connected between the first node N1 and a second voltage V2 lower than the first voltage V1. The second voltage divider 221 may include a third resistor R3 connected between a third voltage V3 and a second node N2 and a fourth resistor R4 connected between the second node N2 and a fourth voltage V4 lower than the third voltage V3.

In some example embodiments, resistance values of the division resistors R1, R2, R3 and R4 may be varied based on the reflection characteristic at the input-output node NIO to adjust voltage levels of the first control voltage VCP and the second control voltage VCN. In other words, at least one of the first resistor R1 and the second resistor R2 may be implemented with a variable resistor such that a resistance value of the variable resistor is varied based on the reflection characteristic at the input-output node NIO, and at least one of the third resistor R3 and the fourth resistor R4 may be a variable resistor such that a resistance value of the variable resistor is varied based on the reflection characteristic at the input-output node NIO.

For example, as illustrated in FIG. 3, the first resistor R1 may be a variable resistor having a resistance value varied based on a first control signal C1, and the fourth resistor R4 may be another variable resistor having a resistance value varied based on a second control signal C2. The first control signal C1 and the second control signal C2 may have values that are determined based on the reflection characteristic at the input-output node NIO. For example, the first control signal C1 and the second control signal C2 may be generated based on control values stored in a mode register set (MRS) that is included in the internal circuit INTS in FIG. 1. The control values are determined through testing processes of the system including the reception interface circuit 51. The voltage level of the first control voltage VCP may be adjusted by changing the value of the first control signal C1, that is, the resistance value of the first resistor R1. The voltage level of the second control voltage VCN may be adjusted by changing the value of the second control signal C2, that is, the resistance value of the fourth resistor R4.

In other example embodiments, the levels of the voltages V1, V2, V3 and V4 provided to the voltage dividers 211 and 221 may be varied based on the reflection characteristic at the input-output node NIO to adjust voltage levels of the first control voltage VCP and the second control voltage VCN. For example, the voltage levels of the first voltage V1 and V3 may be increased to increase the voltage levels of the first control voltage VCP and the second control voltage VCN, respectively, and vice versa.

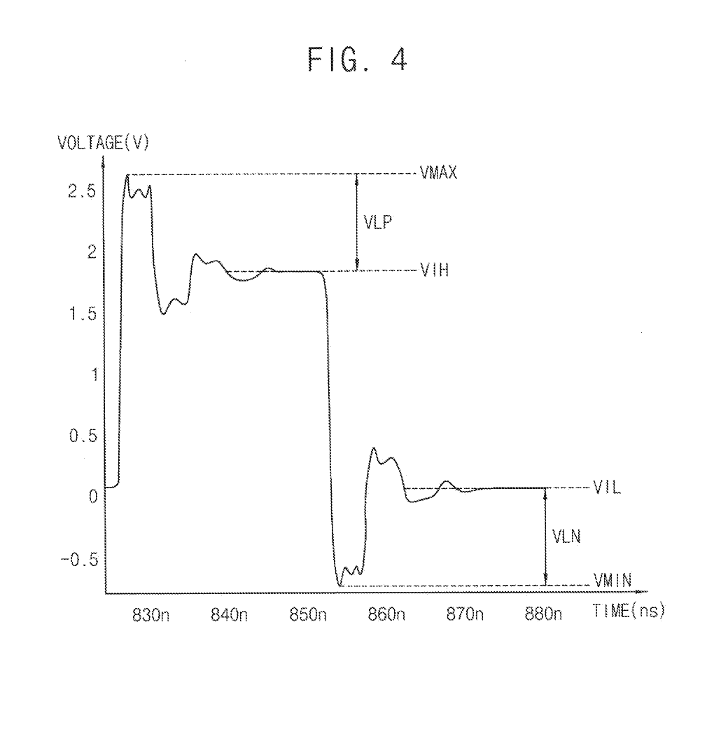

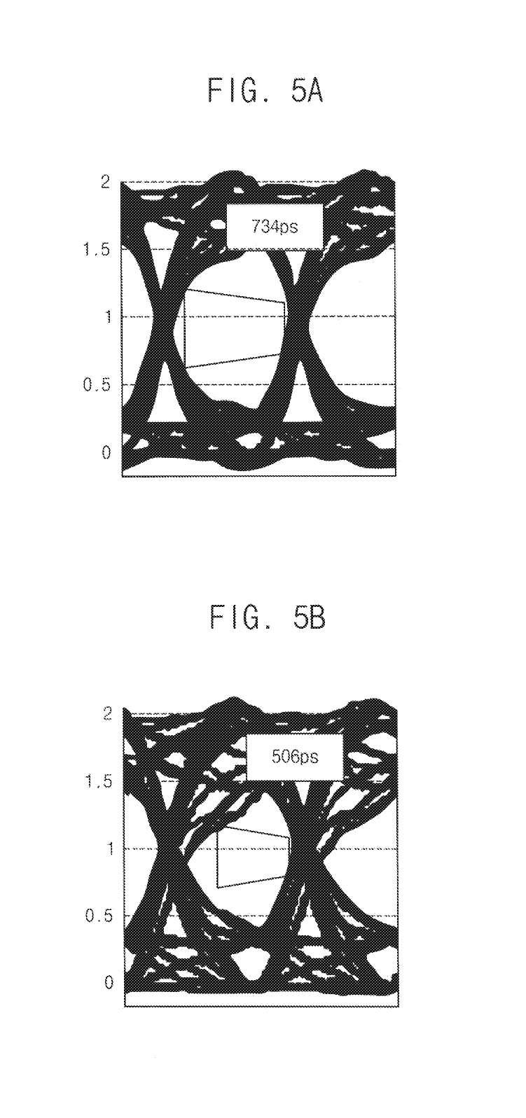

FIG. 4 is a waveform diagram for describing a reception characteristic of a reception interface circuit, and FIGS. 5A and 5B are waveform diagrams illustrating eye margins depending on a limiting voltage.

FIG. 4 illustrates an example waveform at the input-output pad PADS, that is, the input-output node NIO of the second device 40 in FIG. 1 when the transmission driver DR of the first device 20 transmits a pulse. In FIG. 4, the horizontal axis indicates a time in unit of ns (nanosecond) and the vertical axis indicates a voltage in unit of V(volt).

Even though it is ideal that the input signal SI swings between a high voltage level VIH and a low voltage level VIL, the real input signal SI may swing between a maximum voltage level VMAX higher than the high voltage level VIH and a minimum voltage level VMIN lower than the low voltage level VIL due to the signal reflection by impedance mismatching. The difference between the maximum voltage level VMAX and the high voltage level VIH may be referred to as a first limit voltage VLP and the difference between the low voltage level VIL and the minimum voltage level VMIN may be referred to as a second limit voltage VLN. If the limit voltages VLP and VLN are increased, the eye margin of the input signal SI is decreased and thus the performance of the transceiver system is degraded. The limit voltages VLP and VLN may correspond to the above-mentioned reflection characteristic at the input-output node NIO.

FIGS. 5A and 5B illustrate example eye diagrams at the input-output node NIO of the second device 40 in FIG. 1 when the transmission driver DR of the first device 20 transmits a pseudorandom bit stream of 1 Gbps (giga bits per second). FIG. 5A illustrates the eye diagram when the limit voltage is relatively low (about 0.1V) and FIG. 5B illustrates the eye diagram when the limit voltage is relatively high (about 0.4V). In FIGS. 5A and 5B, the horizontal axis indicates a time and the vertical axis indicates a voltage in unit of V(volt).

The eye margin is relatively large, about 734 ps (picosecond), when the limit voltage is relatively low, about 0.1V, as illustrated in FIG. 5A, and the eye margin is relatively small, about 506 ps, when the limit voltage is relatively high, about 0.4V, as illustrated in FIG. 5B. As such, the eye margin is decreased as the limit voltage at the input-output node NIO is increased, and thus the performance of the reception interface circuit may be enhanced by reducing the limit voltage at the input-output node NIO to increase the eye margin. However, the power consumption of the reception interface circuit is increased as the limit voltage at the input-output node NIO is decreased.

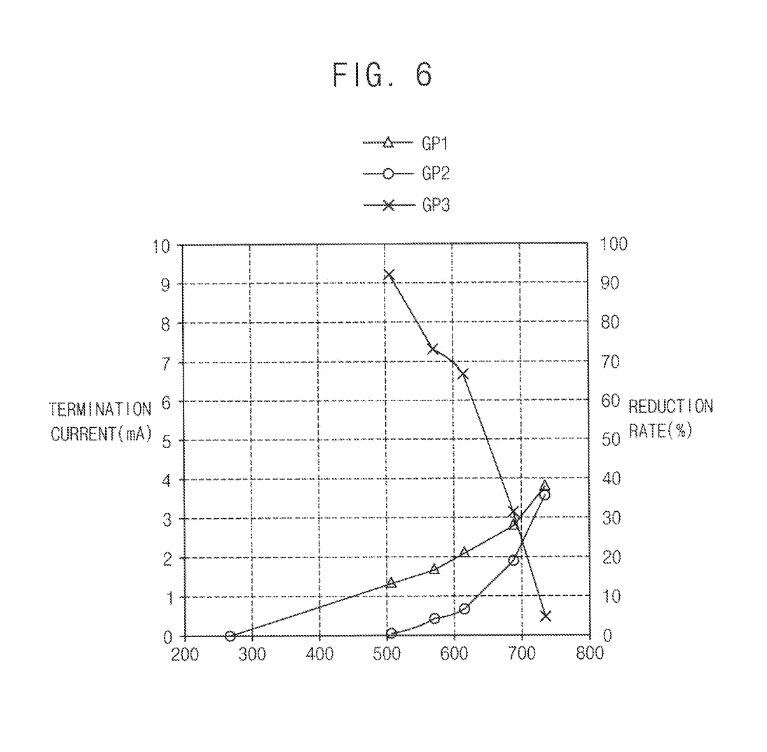

FIG. 6 is a diagram for describing power consumption of a reception interface circuit according to example embodiments.

In FIG. 6, a first graph GP1 indicates a first termination current in a conventional termination circuit, a second graph GP2 indicates a second termination current in a reception limiting circuit according to an example embodiment, and a third graph GP3 indicates a reduction rate of the second termination current with respect to the first termination current. In FIG. 6, the horizontal axis indicates an eye margin in unit of ps and the vertical axis indicates a current in unit of mA(miliampere) and a percentage (%).

Referring to FIG. 6, the reception interface circuit according to example embodiments may consume less power than the conventional termination circuit because the reception interface circuit operates with the reduced current. The reception interface circuit according to example embodiments may provide the increased eye margin in comparison with the conventional termination circuit having the same power consumption. In other words, the reception interface circuit according to example embodiments may have the reduced power consumption in comparison with the conventional termination circuit having the same eye margin.

As illustrated in FIG. 6, the termination current of the reception interface circuit is increased as the eye margin is increased. In other words, the power consumption is increased as the limit voltages VLP and VLN illustrated in FIG. 4 are decreased to enhance the eye margin. As such, there is a trade-off between the power consumption and the reception performance such that one has to be sacrificed for the other. Accordingly, the control voltages VCP and VCN have to be adjusted to have proper voltage levels considering the eye margin and the power consumption.

In some example embodiments, the reception limiting circuit according to example embodiments may perform the above-mentioned reflection-limiting function to limit at least one of the maximum voltage level and the minimum voltage level of the input signal and simultaneously perform an electrostatic discharge (ESD) protection function and a termination function of the input-output node NIO. As the limit voltages VLP and VLN are decreased, the power consumption may be increased but the ESD protection function and the termination function may be reinforced.

FIG. 7 is a diagram illustrating a reception interface circuit according to an example embodiment.

Referring to FIG. 7, a reception interface circuit 52 may include a reception limiting circuit 102, a reception buffer BF and a voltage generation circuit 202. The reception buffer BF receives an input signal SI through an input-output node NIO to generate a buffer signal BF. The voltage generation circuit 202 generates first and second control voltages VCP and VCN based on a reflection characteristic at the input-output node NIO. The reception limiting circuit 102 is connected to the input-output node NIO and limits at least one of a maximum voltage level and a minimum voltage level of the input signal SI based on the first and second control voltages VCP and VCN.

The reception limiting circuit 102 may include a first reflection limiter TP and a second reflection limiter TN. The first reflection limiter TP is connected between the input-output node NIO and a first power supply voltage VDDQ. The first reflection limiter TP limits the maximum voltage level of the input signal based on the first control voltage VCP. The second reflection limiter TN is connected between the input-output node NIO and a second power supply voltage VSSQ lower than the first power supply voltage VDDQ. The second reflection limiter TN limits the minimum voltage level of the input signal SI based on the second control voltage VCN. The first power supply voltage VDDQ may be a positive voltage and the second power supply voltage VSSQ may be a ground voltage having a voltage level of 0V.

As illustrated in FIG. 7, the first reflection limiter TP and the second reflection limiter TN may be implemented using metal oxide semiconductor transistors. The first reflection limiter TP may include a PMOS transistor connected between the input-output node NIO and the first power supply voltage VDDQ and the first control voltage VCP may be applied to a gate electrode of the PMOS transistor. The second reflection limiter TN may include an NMOS transistor connected between the input-output node NIO and the second power supply voltage VSSQ and the second control voltage VCN may be applied to a gate electrode of the NMOS transistor.

The voltage generation circuit 202 may include a first charge pump 212 configured to generate the first control voltage VCP and a second charge pump 222 configured to generate the second control voltage VCN.

The first charge pump 212 performs a voltage-increasing operation based on the first power supply voltage VDDQ and the second power supply voltage VSSQ. That is, the first charge pump 212 may perform the voltage-increasing operation to provide a voltage (VDDQ+dV) higher than the first power supply voltage VDDQ as the first control voltage VCP.

The second charge pump 222 performs a voltage-decreasing operation based on the first power supply voltage VDDQ and the second power supply voltage VSSQ. That is, the second charge pump 222 may perform the voltage-decreasing operation to provide a voltage (VSSQ-dV) lower than the second power supply voltage VSSQ as the second control voltage VCN. The second power supply voltage VSSQ may be a ground voltage (that is, 0V) and in this case the second charge pump 222 may provide a negative voltage (−dV) as the second control voltage VCN.

The first charge pump 212 performing the voltage-increasing operation and the second charge pump 222 performing the voltage-decreasing operation may be implemented variously. For example, the first charge pump 212 may be implemented as a boost converter and the second charge pump 222 may be implemented as a buck converter.

The first charge pump 212 may vary the voltage level of the first control voltage VCP based on a first control signal C1 and the second charge pump 222 may vary the voltage level of the second control voltage VCN based on a second control signal C2. The first control signal C1 and the second control signal C2 may have values that are determined based on the reflection characteristic at the input-output node NIO. For example, the first control signal C1 and the second control signal C2 may be generated based on control values stored in a mode register set (MRS) that is included in the internal circuit INTS in FIG. 1. The control values may be determined through testing processes of the system including the reception interface circuit 52.

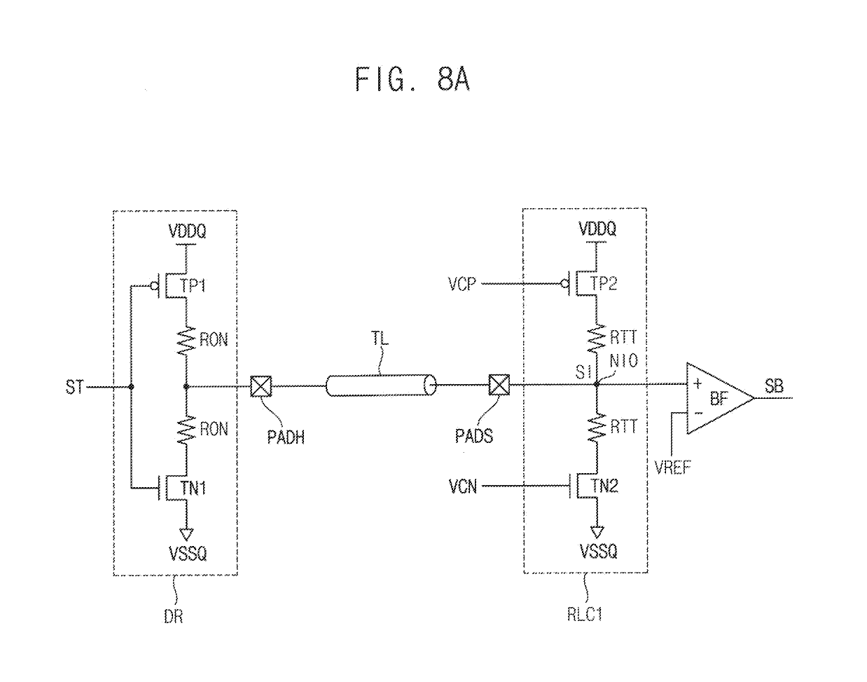

FIGS. 8A and 8B are diagrams for describing a reception interface circuit of a center-tapped termination (CTT) scheme.

Referring to FIG. 8A, a transmission driver DR in a transmitter device may drive an input-output pad PADH based on a transmission signal ST from an internal circuit of the transmitter device. The input-output pad PADH of the transmitter device may be connected to an input-output pad PADS of a receiver device through a transmission line TL. A reception interface circuit RLC1 of the CTT scheme may be connected to the input-output pad PADS of the receiver device. The reception buffer BF in the receiver device may compare the input signal SI through the input-output pad PADS with the reference voltage VREF to provide the buffer signal SB to an internal circuit of the receiver device.

The transmission driver DR may include a pull-up unit connected between a first power supply voltage VDDQ and the input-output pad PADH and a pull-down unit connected between the input-output pad PADH and a second power supply voltage VSSQ lower than the first power supply voltage VDDQ. The pull-up unit may include a turn-on resistor RON and a PMOS transistor TP1 that is switched in response to the transmission signal ST. The pull-down unit may include a turn-on resistor RON and an NMOS transistor TN1 that is switched in response to the transmission signal ST. The turn-on resistors RON may be omitted and each turn-on resistor RON may represent a resistance between the voltage node and the input-output pad PADH when each of the transistors TP1 and TN1 is turned on.

The reception interface circuit RLC1 of the CTT scheme may include a first reflection limiter connected between the first power supply voltage VDDQ and the input-output pad PADS and a second reflection limiter connected between the input-output pad PADS and the second power supply voltage VSSQ. The first reflection limiter may include a termination resistor RTT and a PMOS transistor TP2 configured to limit the maximum voltage level VMAX of the input signal SI based on the first control voltage VCP. The termination resistor RTT and the PMOS transistor TP2 may be connected in series between the first power supply voltage VDDQ and the input-output node NIO. The second reflection limiter may include a termination resistor RTT and an NMOS transistor TN2 configured to limit the minimum voltage level VMIN of the input signal SI based on the second control voltage VCN. The termination resistor RTT and the NMOS transistor TN2 may be connected in series between the second power supply voltage VSSQ and the input-output node NIO. The termination resistors RTT may be omitted and each termination resistor RTT may represent a resistance between the voltage node and the input-output pad PADS when each of the transistors TP2 and TN2 is turned on.

In case of the reception interface circuit RLC1 of the CTT scheme in FIG. 8A, the high voltage level VIH and the low voltage level VIL of the input signal SI may be represented as FIG. 8B. The second power supply voltage VSSQ may be assumed to be a ground voltage (i.e., VSSQ=0) and the voltage drop along the transmission line TL, etc. may be neglected. Thus the high voltage level VIH, the low voltage level VIL and the optimal reference voltage VREF may be calculated as Expression 1.

VIH=VDDQ*(RON+RTT)/(2RON+RTT),

VIL=VDDQ*RON/(2RON+RTT),

VREF=(VIH+VIL)/2=VDDQ/2 Expression 1

Using such reception interface circuit RLC1, the maximum voltage level VMAX and the minimum voltage level VMIN, or the first limit voltage VLP and the second limit voltage VLN as described with reference to FIG. 4 may be controlled.

FIG. 9 is a diagram illustrating an example of a reference voltage generator included in a voltage generation circuit in FIG. 1.

FIG. 9 illustrates a reference voltage generator RVG of a resistance division scheme. The configuration of FIG. 9 is a non-limiting example for describing a relation between a control code CCD and the reference voltage VREF, and the reference voltage generator RVG may be implemented with an arbitrary digital-to-analog converter (DAC) of various configurations.

Referring to FIG. 9, the reference voltage generator RVG may include a plurality of division resistors R and a plurality of switches SW1˜SWk. The division resistors R may be connected in series between a first division node N1 and a k-th division node Nk. A first voltage VR1 may be applied to the first division node N1 and a second voltage VR2 lower than the first voltage VR1 may be applied to the k-th node Nk. For example, the first voltage VR1 may be a power supply voltage and the second voltage VR2 may be a ground voltage. The switches SW1˜SWk may be connected in parallel between the division nodes N1˜Nk and an output node NO. The switches SW1˜SWk may control electrical connections between the division nodes N1˜Nk and the output node NO in response to code bits C[1]˜C[k] of the control code CCD, respectively. For example, only one of the code bits C[1]˜C[k] may be activated at one time as a thermometer code and the switch corresponding to the activated code bit may be turned on to provide the voltage of the corresponding division node to the output node NO as the reference voltage VREF.

The maximum voltage level VMAX and the minimum voltage level VMIN of the input signal SI as described with reference to FIG. 4 may be detected by sequentially changing the control code CCD. The sequential change of the control code CCD may be performed by selectively activating the code bits C[1]˜C[k]. The sequentially-increasing reference voltage VREF may be provided by sequentially activating the code bits C[1]˜C[k] one by one from the first code bit C[1] to the k-th code bit C[k]. In contrast, the sequentially-decreasing reference voltage VREF may be provided by sequentially activating the code bits C[1]˜C[k] one by one from the k-th code bit C[k] to the first code bit C[1]. As such, using the sequentially increasing or decreasing reference voltage VREF, the limit voltages VLP and VLN at the input-output node NIO as described with reference to FIG. 4 may be detected. The voltage levels of the above-mentioned control voltages VCP and VCN may be adjusted adaptively based on the limit voltages VLP and VLN at the input-output node NIO, that is the reflection characteristic at the input-output node NIO.

FIGS. 10 and 11 are diagrams for describing a reception interface circuit of a pseudo-open drain (POD) termination scheme.

Referring to FIG. 10, a transmission driver DR in a transmitter device may drive an input-output pad PADH based on a transmission signal ST from an internal circuit of the transmitter device. The input-output pad PADH of the transmitter device may be connected to an input-output pad PADS of a receiver device through a transmission line TL. A reception interface circuit RLC2 of a first POD termination scheme may be connected to the input-output pad PADS of the receiver device. The reception buffer BF in the receiver device may compare the input signal SI through the input-output pad PADS with the reference voltage VREF to provide the buffer signal SB to an internal circuit of the receiver device.

The transmission driver DR may include a pull-up unit connected between a first power supply voltage VDDQ and the input-output pad PADH and a pull-down unit connected between the input-output pad PADH and a second power supply voltage VSSQ lower than the first power supply voltage VDDQ. The pull-up unit may include a turn-on resistor RON and a PMOS transistor TP1 that is switched in response to the transmission signal ST. The pull-down unit may include a turn-on resistor RON and an NMOS transistor TN1 that is switched in response to the transmission signal ST. The turn-on resistors RON may be omitted and each turn-on resistor RON may represent a resistance between the voltage node and the input-output pad PADH when each of the transistors TP1 and TN1 is turned on.

The reception interface circuit RLC2 of the first POD termination scheme may include a termination resistor RTT and an NMOS transistor TN2 configured to limit the minimum voltage level VMIN of the input signal SI based on the control voltage VCN. The termination resistor RTT and the NMOS transistor TN2 may be connected in series between the input-output node NIO and the second power supply voltage. VSSQ. The termination resistor RTT may be omitted and the termination resistor RTT may represent a resistance between the voltage node and the input-output pad PADS when the NMOS transistor TN2 is turned on.

The second power supply voltage VSSQ may be assumed to be a ground voltage (i.e., VSSQ=0) and the voltage drop along the transmission line TL, etc may be neglected. Thus the high voltage level VIH, the low voltage level VIL and the optimal reference voltage VREF may be calculated as Expression 2.

VIH=VDDQ*RTT/(RON+RTT),

VIL=VSSQ=0,

VREF=(VIH+VIL)/2=VDDQ*RTT/2(RON+RTT) Expression 2

Using such reception interface circuit RLC2, the minimum voltage level VMIN, or the second limit voltage VLN as described with reference to FIG. 4 may be controlled.

Referring to FIG. 11, a transmission driver DR in a transmitter device may drive an input-output pad PADH based on a transmission signal ST from an internal circuit of the transmitter device. The input-output pad PADH of the transmitter device may be connected to an input-output pad PADS of a receiver device through a transmission line TL. A reception limiting circuit RLC3 of a second POD termination scheme may be connected to the input-output pad PADS of the receiver device for impedance matching. The reception buffer BF in the receiver device may compare the input signal SI through the input-output pad PADS with the reference voltage VREF to provide the buffer signal SB to an internal circuit of the receiver device.

The transmission driver DR may include a pull-up unit connected between a first power supply voltage VDDQ and the input-output pad PADH and a pull-down unit connected between the input-output pad PADH and a second power supply voltage VSSQ lower than the first power supply voltage VDDQ. The pull-up unit may include a turn-on resistor RON and a PMOS transistor TP1 that is switched in response to the transmission signal ST. The pull-down unit may include a turn-on resistor RON and an NMOS transistor TN1 that is switched in response to the transmission signal ST. The turn-on resistors RON may be omitted and each turn-on resistor RON may represent a resistance between the voltage node and the input-output pad PADH when each of the transistors TP1 and TN1 is turned on.

The reception interface circuit RLC3 of the second POD termination scheme may include a termination resistor RTT and a PMOS transistor TP2 configured to limit the maximum voltage level VMAX of the input signal SI based on the control voltage VCP. The termination resistor RTT and the PMOS transistor TP2 may be connected in series between the first power supply voltage VDDQ and the input-output node NIO. The termination resistor RTT may be omitted and the termination resistor RTT may represent a resistance between the voltage node and the input-output pad PADS when the NMOS transistor TN2 is turned on.

The second power supply voltage VSSQ may be assumed to be a ground voltage (i.e., VSSQ=0) and the voltage drop along the transmission line TL, etc may be neglected. Thus the high voltage level VIH, the low voltage level VIL and the optimal reference voltage VREF may be calculated as Expression 3.

VIH=VDDQ,

VIL=VDDQ*RON/(RON+RTT),

VREF=(VIH+VIL)/2=VDDQ*(2RON+RTT)/2(RON+RTT) Expression 3

Using such reception interface circuit RLC3, the maximum voltage level VMAX, or the first limit voltage VLP as described with reference to FIG. 4 may be controlled.

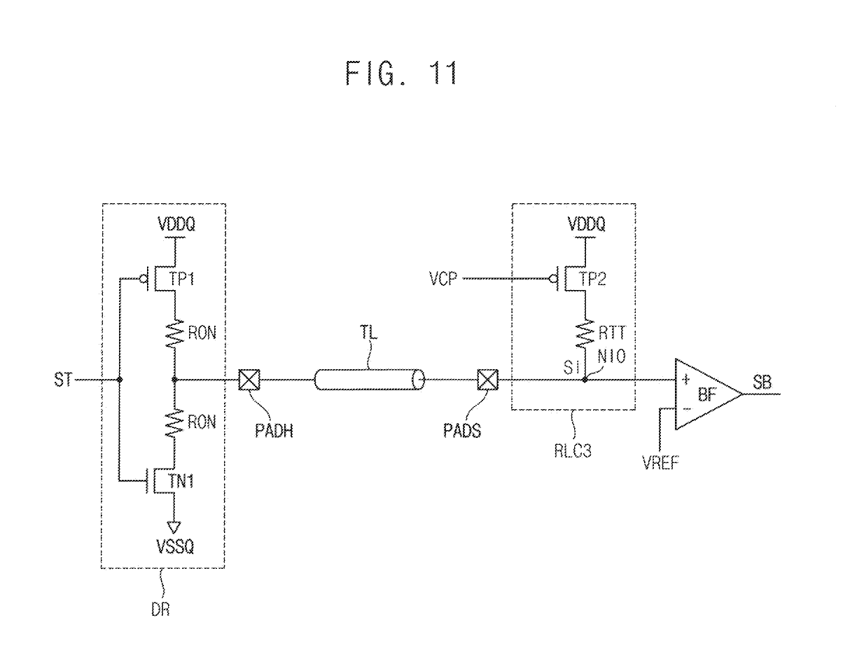

FIG. 12 is a block diagram illustrating a memory system according to example embodiments.

Referring to FIG. 12, a memory system 11 may include a memory controller 21 and a memory device 41. The memory controller 21 may control the memory device 41 in response to signals received from an external device such as a host, an application processor, etc. For example, the memory controller 21 may transfer data DATA, an address ADDR, a command CMD and a control signal CTRL to the memory device 41 in response to the request from the external device.

The memory device 41 may perform the read operation, the write (program) operation, the erase operation, etc. according to the control of the memory controller 21.

The memory device 41 may include a reception interface circuit RIC1 as described with reference to FIGS. 1 through 11. In addition, the memory controller 21 may include a reception interface circuit RIC2 as described with reference to FIGS. 1 through 11. The reception interface circuits RIC1 and RIC2 may be included in the memory device 41 and the memory controller 21 respectively for receiving the high-speed data transferred bi-directionally.

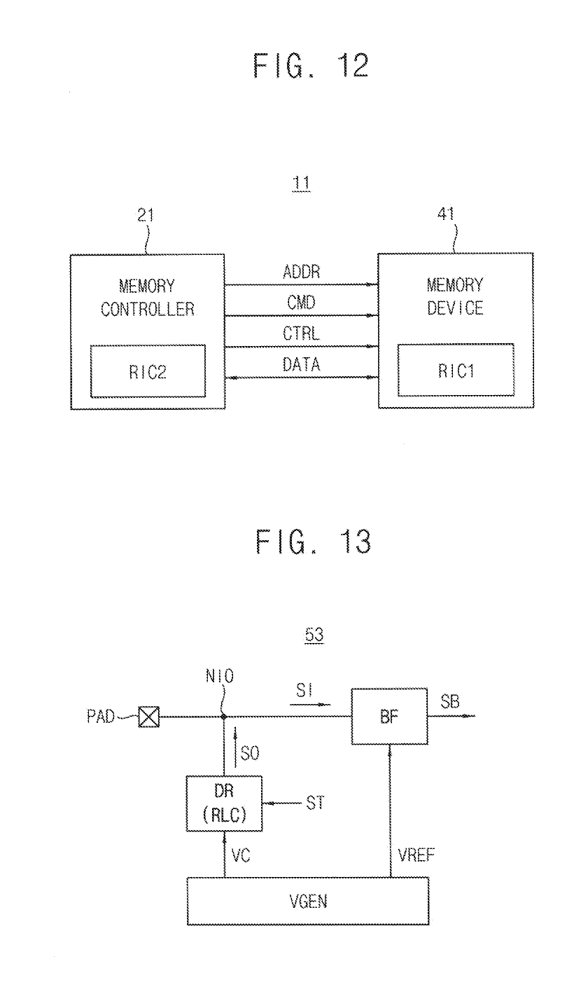

FIG. 13 is a diagram illustrating an interface circuit according to an example embodiment.

Referring to FIG. 13, an interface circuit 53 may include a reception buffer BF, a transmission driver DR and a voltage generation circuit VGEN.

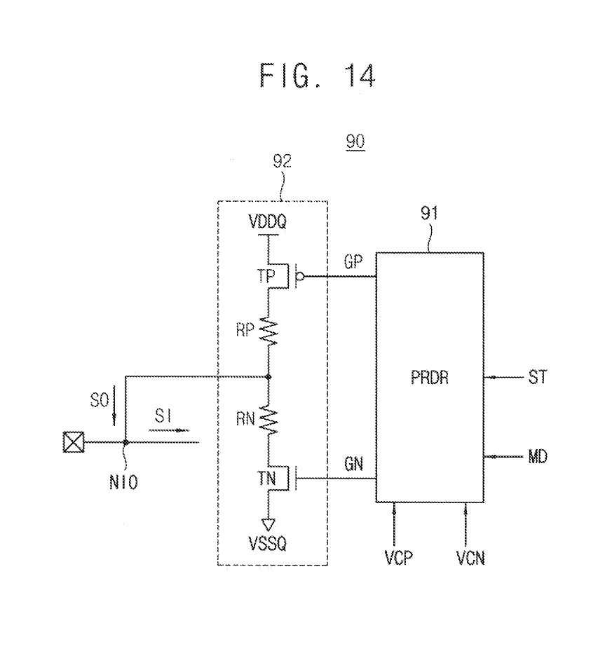

The reception buffer BF may buffer an input signal SI provided through an input-output pad PAD to transfer a buffer signal SB to an internal circuit. The transmission driver DR may output an output signal SO to the input-output pad PAD based on a transmission signal ST provided from the internal circuit. As will be described below with reference to FIG. 14, a reception interface circuit RLC according to example embodiments may be included in the transmission driver DR that drives the input-output pad PAD, that is, the input-output node NIO.

The termination circuit ODT may change the termination mode in response to a termination control signal TCON. The buffer block BFBK may change the reception characteristic of itself in response to a buffer control signal BCON. The interface controller ICTRL may generate the termination control signal TCON and the buffer control signal BCON such that the reception characteristic of the buffer block is changed in association with a change of the termination mode.

The voltage generation circuit VGEN generates at least one control voltage VC based on the reflection characteristic at the input-output node NIO. The voltage generation circuit VGEN may further generate a reference voltage VREF provided to the reception buffer BF. The reception limiting circuit RLC is connected to the input-output node NIO and limits at least one of a maximum voltage level and a minimum voltage level of the input signal SI based on the control voltage VC.

FIG. 14 is a diagram illustrating an example embodiment of a transmission driver included in the interface circuit of FIG. 13.

Referring to FIG. 14, a transmission driver 90 may include a pre-driver PRDR 91 and a driving unit 92. The pre-driver 91 may generate a first driving signal GP and a second driving signal GN based on a transmission signal, a first control voltage VCP, a second control voltage VCN and a mode signal MD. The driving unit 92 may drive the input-output node NIO based on the first driving signal GP and the second driving signal GN.

In some example embodiments, the driving unit 92 may include a pull-up unit connected between the first power supply voltage VDDQ and the input-output node NIO and a pull-down unit connected between the input-output node NIO and the second power supply voltage VSSQ. The pull-up unit may include a resistor RP and a PMOS transistor TP that is switched in response to the first driving signal GP. The pull-down unit may include a resistor RN and an NMOS transistor TN that is switched in response to the second driving signal GN. The resistors RP and RN may be omitted and each of the resistors RP and RN may represent a resistance between the voltage node and the input-output node NIO when each of the transistors TP and TN is turned on.

When the mode signal MD indicates a transmission mode, the pre-driver 91 may perform the first driving signal GP1 and the second driving signal GN regardless of the first control voltage VCP and the second control voltage VCN. In the transmission mode, the pre-driver 91 may determine the logic levels of the first driving signal GP and the second driving signal GN based on the logic level of the transmission signal ST, and thus the driving unit 92 may perform the transmission operation such that the output signal SO is output to the input-output node NIO based on the transmission signal ST.

When the mode signal MD indicates a reception mode, the pre-driver 91 may perform the first driving signal GP1 and the second driving signal GN regardless of the transmission signal ST. In the reception mode, the pre-driver 91 may provide t the first control voltage VCP as the first driving signal GP and the second control voltage VCN as the second driving signal GN. As described above, the first control voltage VCP and the second control voltage VCN have the voltage levels based on the reflection characteristic at the input-output node NIO to limit the maximum voltage level VMAX and the minimum voltage level VMIN of the input signal SI.

As such, the driving unit 92 in the transmission driver 90 may be used as the reception limiting circuit during the reception operation and thus the size of the interface circuit may be reduced.

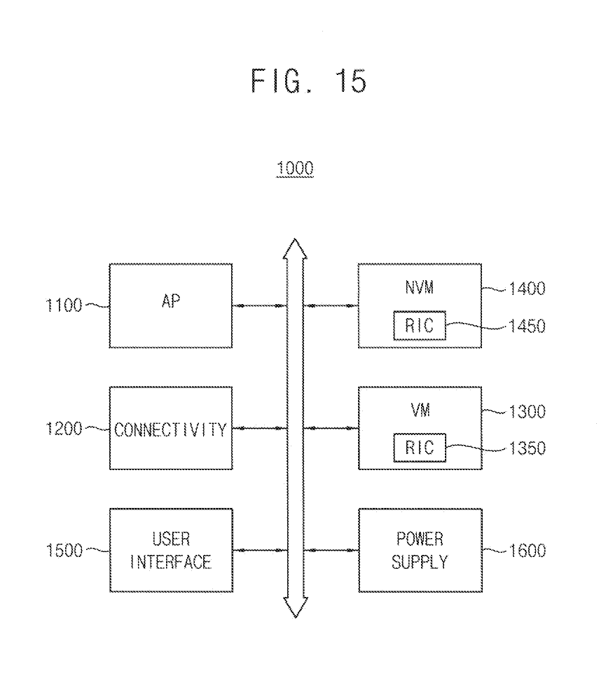

FIG. 15 is a block diagram illustrating a mobile system according to example embodiments.

Referring to FIG. 15, a mobile system 1000 includes an application processor (AP) 1100, a connectivity unit 1200, a volatile memory device (VM) 1300, a nonvolatile memory device (NVM) 1400, a user interface 1500, and a power supply 1600.

The application processor 1100 may execute applications such as a web browser, a game application, a video player, etc. The connectivity unit 1200 may perform wired or wireless communication with an external device. The volatile memory device 1300 may store data processed by the application processor 1100, or may operate as a working memory. For example, the volatile memory device 1300 may be a dynamic random access memory, such as double data rate synchronous dynamic random-access memory (DDR SDRAM), low power double data rate synchronous dynamic random-access memory (LPDDR SDRAM), graphic double data rate synchronous dynamic random-access memory (GDDR SDRAM), rambus dynamic random access memory (RDRAM), etc. The nonvolatile memory device 1400 may store a boot image for booting the mobile system 1000. The user interface 1500 may include at least one input device, such as a keypad, a touch screen, etc., and at least one output device, such as a speaker, a display device, etc. The power supply 1600 may supply a power supply voltage to the mobile system 1000.

The volatile memory device 1300 may include a reception interface circuit RIC1350 and/or the nonvolatile memory device 1400 may include a reception interface circuit RIC1450 as described with reference to FIGS. 1 through 14. As described above, the reception interface circuit RIC may include a reception buffer, a voltage generation circuit and a reception limiting circuit. The reception buffer receives an input signal through an input-output node to generate a buffer signal. The voltage generation circuit generates at least one control voltage based on a reflection characteristic at the input-output node. The reception limiting circuit is connected to the input-output node and limits at least one of a maximum voltage level and a minimum voltage level of the input signal based on the control voltage.

As such, the reception interface circuit and the memory system according to example embodiments may reduce power consumption by limiting at least one of the maximum voltage level and the minimum voltage level of the input signal based on the reception characteristic at the input-output node using the reception limiting circuit. The power consumption and the performance of the reception interface circuit and the memory system may be controlled conveniently by adjusting the level of the control voltage. In addition, the reception interface circuit according to example embodiments may provide an increased eye margin in comparison with a conventional termination circuit having the same power consumption.

The present inventive concept may be applied to any devices and systems including an interface circuit for transferring signals. For example, the present inventive concept may be applied to systems such as be a mobile phone, a smart phone, a personal digital assistant (PDA), a portable multimedia player (PMP), a digital camera, a camcorder, personal computer (PC), a server computer, a workstation, a laptop computer, a digital TV, a set-top box, a portable game console, a navigation system, etc.

The foregoing is illustrative of example embodiments and is not to be construed as limiting thereof. Although a few example embodiments have been described, those skilled in the art will readily appreciate that many modifications are possible in the example embodiments without materially departing from the present inventive concept.

What is claimed is:

1. A reception interface circuit comprising:
a reception buffer configured to receive an input signal through an input-output node to generate a buffer signal;
a voltage generation circuit configured to generate at least one control voltage based on a reflection characteristic at the input-output node; and
a reception limiting circuit connected to the input-output node and configured to limit at least one of a maximum voltage level and a minimum voltage level of the input signal based on the at least one control voltage.

2. The reception interface circuit of claim 1, wherein the reception limiting circuit includes:
a first reflection limiter connected between the input-output node and a first power supply voltage and configured to limit the maximum voltage level of the input signal based on a first control voltage of the at least one control voltage; and
a second reflection limiter connected between the input-output node and a second power supply voltage lower than the first power supply voltage and configured to limit the minimum voltage level of the input signal based on a second control voltage of the at least one control voltage.

3. The reception interface circuit of claim 2, wherein
the first reflection limiter includes a P-channel metal oxide semiconductor (PMOS) transistor connected between the input-output node and the first power supply voltage, the first control voltage being applied to a gate electrode of the PMOS transistor, and
the second reflection limiter includes an N-channel metal oxide semiconductor (NMOS) transistor connected between the input-output node and the second power supply voltage, the second control voltage being applied to a gate electrode of the NMOS transistor.

4. The reception interface circuit of claim 2, wherein the voltage generation circuit includes:
a first voltage divider configured to generate the first control voltage; and
a second voltage divider configured to generate the second control voltage.

5. The reception interface circuit of claim 4, wherein the first voltage divider includes:
a first resistor connected between a first voltage and a first node; and
a second resistor connected between the first node and a second voltage lower than the first voltage, and
wherein at least one of the first resistor and the second resistor is a variable resistor such that a resistance value of the variable resistor varies based on the reflection characteristic at the input-output node.

6. The reception interface circuit of claim 4, wherein the second voltage divider includes:
a third resistor connected between a third voltage and a second node; and
a fourth resistor connected between the second node and a fourth voltage lower than the third voltage, and
wherein at least one of the third resistor and the fourth resistor is a variable resistor such that a resistance value of the variable resistor is varied based on the reflection characteristic at the input-output node.

7. The reception interface circuit of claim 2, wherein the voltage generation circuit includes:
a first charge pump configured to generate the first control voltage; and
a second charge pump configured to generate the second control voltage.

8. The reception interface circuit of claim 7, wherein the first charge pump performs a voltage-increasing operation to provide a voltage higher than a power supply voltage as the first control voltage, and the second charge pump performs a voltage-decreasing operation to provide a negative voltage as the second control voltage.

9. The reception interface circuit of claim 2, wherein
the first reflection limiter includes a PMOS transistor connected between the input-output node and the first power supply voltage and a pull-up resistor connected in series with the PMOS transistor between the input-output node and the first power supply voltage, the first control voltage being applied to a gate electrode of the PMOS transistor, and
the second reflection limiter includes an NMOS transistor connected between the input-output node and the second power supply voltage and a pull-down transistor connected in series with the NMOS transistor between the input-output node and the second power supply voltage, the second control voltage being applied to a gate electrode of the NMOS transistor.

10. The reception interface circuit of claim 1, further comprising:
a transmission driver configured to drive the input-output node,
wherein the reception limiting circuit is included in the transmission driver.

11. The reception interface circuit of claim 1, wherein the reception limiting circuit is connected between a power supply voltage and the input-output node and the reception limiting circuit limits the maximum voltage level of the input signal based on the at least one control voltage.

12. The reception interface circuit of claim 1, wherein the reception limiting circuit is connected between a ground voltage and the input-output node and the reception limiting circuit limits the minimum voltage level of the input signal based on the at least one control voltage.

13. The reception interface circuit of claim 1, wherein the reception limiting circuit performs a reflection-limiting function to limit at least one of the maximum voltage level and the minimum voltage level of the input signal and simultaneously performs an electrostatic discharge protection function and a termination function of the input-output node.

14. The reception interface circuit of claim 1, wherein the voltage generation circuit generates the at least one the control voltage further based on an eye margin and a power consumption of the reception interface circuit.

15. A memory system comprising:
a memory device including,
a reception buffer configured to receive an input signal from a memory controller through an input-output node to generate a buffer signal,
a voltage generation circuit configured to generate at least one control voltage based on a reflection characteristic at the input-output node, and
a reception limiting circuit connected to the input-output node and configured to limit at least one of a maximum voltage level and a minimum voltage level of the input signal based on the at least one control voltage; and
the memory controller configured to control the memory device.

16. A reception limiting circuit comprising:
an input-output node configured to receive an input signal;
a first reflection limiter connected to the input-output node and configured to limit a maximum voltage level of the input signal based on a first control voltage; and
a second reflection limiter connected to the input-output node and configured to limit a minimum voltage level of the input signal based on a second control voltage.

17. The reception limiting circuit of claim 16, wherein
the first reflection limiter includes a P-channel metal oxide semiconductor (PMOS) transistor connected to the input-output node, the first control voltage being applied to a gate electrode of the PMOS transistor, and
the second reflection limiter includes an N-channel metal oxide semiconductor (NMOS) transistor connected to the input-output node, the second control voltage being applied to a gate electrode of the NMOS transistor.

18. The reception limiting circuit of claim 16, further comprising:
a voltage divider including first and second resistors connected at a first node, at least one of the first and second resistors being a variable resistor such that a resistance value of the variable resistor is varied based on reflection characteristic of the input-output node, the first control voltage being a voltage at the first node; and
a second voltage divider including third and fourth resistors connected at a second node, at least one of the third and fourth resistors being a second variable resistor such that a resistance value of the second variable resistor is varied based on reflection characteristic of the input-output node, the second control voltage being a voltage at the second node.

19. The reception limiting circuit of claim 16, wherein the reception limiting circuit is configured to perform a reflection-limiting function to limit the maximum voltage level and the minimum voltage level of the input signal and simultaneously perform an electrostatic discharge protection function and a termination function of the input-output node.

20. The reception limiting circuit of claim 16, wherein
the first reflection limiter is connected between a power supply voltage and the input-output node, and
the second reflection limiter is connected between a ground voltage and the input-output node.
